(19) United States
(12) Patent Application Publication
(10) Pub. No.: US 2007/0138512 A1
(43) Pub. Date: Jun. 21, 2007

(54) Semiconductor substrate manufacturing method and semiconductor device

(75) Inventor: Kei Kanemoto, Fujimi-machi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Tokyo (JP)

(21) Appl. No.: 11/639,022

(22) Filed: Dec. 14, 2006

(30) Foreign Application Priority Data
Dec. 15, 2005 (JP) 2005-361452

(51) Int. Cl. H01L 27/10

(52) U.S. Cl. 257/211

(57) ABSTRACT

A semiconductor substrate manufacturing method, including: forming, on an active surface side of a semiconductor base material, a first semiconductor layer whose etch selectivity is higher than that of the semiconductor base material; forming over the first semiconductor layer a second semiconductor layer whose etch selectivity is lower than that of the first semiconductor layer; forming a support hole so as to expose the semiconductor base material by partially removing and opening the second and first semiconductor layers around an element region; forming a support formation layer on the active surface side of the semiconductor base material by filling the support hole and covering the second semiconductor layer; forming, through etching, an opening surface that exposes part of end portions of a support and the first and second semiconductor layers located under this support, leaving a region including at least part of a region for the support hole and the element region; forming a cavity between the second semiconductor layer of the element region and the semiconductor base material by selectively etching the first semiconductor layer via the opening surface; forming a buried insulating film in the cavity; forming a planarized insulating film on the active surface side of the semiconductor base material; and removing, after planarizing the active surface side of the second semiconductor layer, the support formation layer remaining at a position where it covers the second semiconductor layer or at least part of a layer derived from the planarized insulating layer so as to expose the element region; wherein, when the selective etch is performed while keeping a maximum width of the element region to be narrower than a width expressed as 2×S×R in which S is a tolerable etch amount of the second semiconductor layer that is etched simultaneously with the first semiconductor layer in the selective etch, and R is a selectivity between the first semiconductor layer and the second semiconductor layer in the selective etch, the first semiconductor layer is removed in a state that a parasitically etched amount of the second semiconductor layer is kept at the tolerable etch amount S or less.

### BACKGROUND

1. Technical Field

The present invention relates to a semiconductor substrate manufacturing method and a semiconductor device manufacturing method. Particularly, it relates to a technique for fabricating a silicon-on-insulator (SOI) structure on a semiconductor substrate.

2. Related Art

A transistor formed on the SOI substrate has a smaller junction capacitance (capacitance between a source/drain region and a substrate) than when formed on a bulk silicon substrate and, therefore, has great advantages that the semiconductor device consumes less electricity and operates faster.

Generally, an SOI substrate which includes an SOI structure formed on the entire surface of a bulk silicon substrate is prepared, and transistors and the like are formed on this SOI structure. The SOI structure is then removed where it is not necessary. When forming the SOI substrate, a laminating technology as disclosed in JP-A-2002-299591 or a separation-by-implanted-oxygen (SIMOX) technology as disclosed in JP-A-2000-124092 is used, for example.

Further, a non-patent document by T Sakai et al. (Second International SiGe Technology and Device Meeting, Meeting Abstract, pp. 230-231, May 2004) discloses a method of separation by bonding Si islands (SBSI), by which transistors can be formed at low cost on the SOI structure by partially forming an SOI layer on a bulk silicon substrate. To form the SOI structure on the bulk silicon substrate by the SBSI method, a silicon germanium (SiGe) layer and a silicon (Si) layer are first epitaxially grown on a silicon substrate, and a hole (a support hole) is formed therein so as to form a support. After forming thereon a silicon oxide layer and the like as the support, the silicon oxide layer, the silicon layer, and the silicon germanium layer around an element region are dry-etched so as to obtain the configuration of the element region. Then, by selectively etching the silicon germanium layer with fluoronitric acid, a cavity is formed under the silicon layer which is supported by the support. Then, by burying an insulating layer such as silicon oxide in this cavity, a buried oxide (BOX) layer is formed between the silicon substrate and the silicon layer. Thereafter, as the substrate surface is planarized to expose the silicon layer at the surface, the SOI structure is obtained on the bulk silicon substrate.

In order to manufacture a laminating substrate by use of the technology disclosed in JP-A-2002-299591, the surface of the silicon wafer needs to be polished after the two silicon substrates are laminated. It is thus difficult to finely control the thickness of the thin semiconductor layer located on the SOI substrate. Also, since the laminating and polishing processes are required, the SOI substrate costs more than does the bulk silicon substrate.

Further, in order to manufacture the SIMOX substrate by use of the technology disclosed in JP-A-2000-124092, it is necessary to ion-implant highly concentrated oxygen in the silicon wafer. Thus, damages caused by the ion implantation may remain in the SOI substrate. Also, there are problems that the throughput decreases because of the need to ion-implant highly concentrated oxygen and that the cost is higher than the bulk silicon substrate.

In contrast, in the method disclosed in Sakai et al's non-patent document, only the silicon germanium layer is selectively removed by using the selectivity between silicon and silicon germanium. However, there is a problem that the silicon germanium layer remains depending on the device structure and manufacture conditions and that germanium contamination is generated.

### SUMMARY

An advantage of the invention is to provide a semiconductor substrate manufacturing method that avoids germanium contamination and to provide a low cost semiconductor device that is capable of faster operation at reduced electric consumption by finely controlling the thickness of a silicon layer in the upper layer of an SOI substrate.

According to an aspect of the invention, a semiconductor substrate manufacturing method includes: forming, on an active surface side of a semiconductor base material, a first semiconductor layer whose etch selectivity is higher than that of the semiconductor base material; forming over the first semiconductor layer a second semiconductor layer whose etch selectivity is lower than that of the first semiconductor layer; forming a support hole so as to expose the semiconductor base material by partially removing and opening the second and first semiconductor layers around an element region; forming a support formation layer on the active surface side of the semiconductor base material by filling the support hole and covering the second semiconductor layer; forming, through etching, an opening surface that exposes part of end portions of a support and the first and second semiconductor layers located under this support, leaving a region including at least part of a region for the support hole and the element region; forming a cavity between the second semiconductor layer of the element region and the semiconductor base material by selectively etching the first semiconductor layer via the opening surface; forming a buried insulating film in the cavity; forming a planarized insulating film on the active surface side of the semiconductor base material; and removing, after planarizing the active surface side of the second semiconductor layer, the support formation layer remaining at a position where it covers the second semiconductor layer or at least part of a layer derived from the planarized insulating layer so as to expose the element region; wherein, when the selective etch is performed while keeping a maximum width of the element region to be narrower than a width expressed as 2×S×R in which S is a tolerable etch amount of the second semiconductor layer that is etched simultaneously with the first semiconductor layer in the selective etch, and R is a selectivity between the first semiconductor layer and the second semiconductor layer in the selective etch, the first semiconductor layer is removed in a state that a parasitically etched amount of the second semiconductor layer is kept at the tolerable etch amount S or less.

According to this semiconductor substrate manufacturing method, the maximum width of the element region composed of the second semiconductor layer is prescribed. By keeping the width of the element region to be narrower than 2×S×R, it becomes possible to keep the parasitic etch amount of the second semiconductor layer to be less than the tolerable etch amount S in a state that the entire first semiconductor layer is removed by the etch. Because it is possible to prevent the second semiconductor layer from being etched beyond its tolerable etch amount S, a fine control of the thickness of the second semiconductor layer is possible. In this case, because the etch of the first semiconductor layer progresses from both sides of the width direction, the element region can take a width by an amount as multiplied by the coefficient 2.

It is preferable that, in the semiconductor substrate manufacturing method, the semiconductor base material be a bulk silicon substrate; the first semiconductor layer be a silicon germanium layer; and the second semiconductor layer be a silicon layer.

According to this semiconductor substrate manufacturing method, because the etch selectivity of the bulk silicon substrate or the silicon layer is lower than that of the silicon germanium layer, it is possible to selectively etch and remove the silicon germanium layer, leaving the bulk silicon and the silicon layer, and to readily form the cavity between the bulk silicon layer and the silicon layer.

According to another aspect of the invention, a semiconductor device has a transistor using, as a composition element, the element region obtained by conducting the semiconductor substrate manufacturing method as described in the first aspect of the invention.

According to this structure, the semiconductor device includes the transistor composed of the element region in a state that the germanium contamination is suppressed. If germanium exists in the formation of a gate oxidation film of the transistor, the germanium is forced through the gate oxidation film and gathers at the interface between the gate oxidation film and the silicon layer which is the second semiconductor layer. This may create leakage current, Qbd deterioration, and decrease in the mobility of the gate oxidation film. In this structure, however, since the germanium contamination is suppressed, the element region may contain the transistor as the semiconductor device with which the occurrence of the above-described problems is controlled.

### BRIEF DESCRIPTION OF THE DRAWINGS

The invention will be described with reference to the accompanying drawings, wherein like numbers reference like elements.

FIG. 1A is a plan diagram to explain a semiconductor substrate manufacturing method according to a first embodiment.

FIG. 1B is a cross-sectional pattern view taken on a line A-A′ of FIG. 1A.

FIG. 2A is a plan diagram to explain the semiconductor substrate manufacturing method according to the first embodiment.

FIG. 2B is a cross-sectional pattern view taken on a line A-A′ of FIG. 2A.

FIG. 3A is a plan diagram to explain the semiconductor substrate manufacturing method according to the first embodiment.

FIG. 3B is a cross-sectional pattern view taken on a line A-A′ of FIG. 3A.

FIG. 4A is a plan diagram to explain the semiconductor substrate manufacturing method according to the first embodiment.

FIG. 4B is a cross-sectional pattern view taken on a line A-A′ of FIG. 4A.

FIG. 5A is a plan diagram to explain the semiconductor substrate manufacturing method according to the first embodiment.

FIG. 5B is a cross-sectional pattern view taken on a line A-A′ of FIG. 5A.

FIG. 6A is a plan diagram to explain the semiconductor substrate manufacturing method according to the first embodiment.

FIG. 6B is a cross-sectional pattern view taken on a line A-A′ of FIG. 6A.

FIG. 7A is a plan diagram to explain the semiconductor substrate manufacturing method according to the first embodiment.

FIG. 7B is a cross-sectional pattern view taken on a line A-A′ of FIG. 7A.

FIG. 8A is a plan diagram to explain the semiconductor substrate manufacturing method according to the first embodiment.

FIG. 8B is a cross-sectional pattern view taken on a line A-A′ of FIG. 8A.

FIG. 9A is a plan diagram to explain the semiconductor substrate manufacturing method according to the first embodiment.

FIG. 9B is a cross-sectional pattern view taken on a line A-A of FIG. 9A.

FIG. 10A is a plan diagram to explain the semiconductor substrate manufacturing method according to the first embodiment.

FIG. 10B is a cross-sectional pattern view taken on a line A-A′ of FIG. 10A.

FIG. 11A is a plan diagram to explain the semiconductor substrate manufacturing method according to a second embodiment.

FIG. 11B is a cross-sectional pattern view taken on a line A-A′ of FIG. 11A.

### DESCRIPTION OF EXEMPLARY EMBODIMENTS

Embodiments of the invention will now be described in accordance with the drawings.

First Embodiment

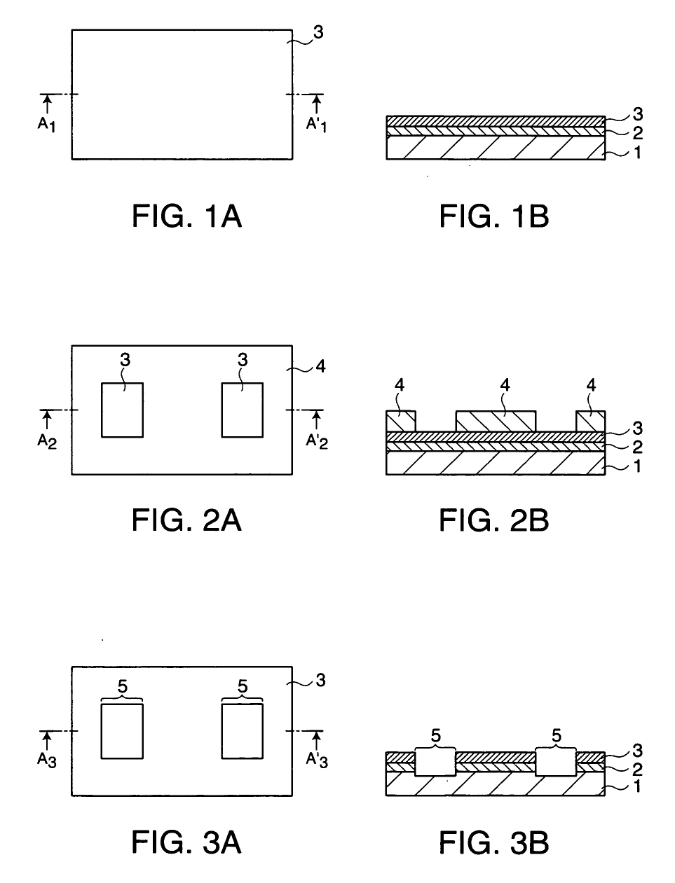

FIGS. 1 through 10 are pattern diagrams illustrating the semiconductor substrate manufacturing method of the first embodiment of one aspect of the invention. More specifically, FIGS. 1A through 10A are plan pattern diagrams, and FIGS. 1B through 10B are cross-sectional pattern diagrams taken on lines A-A′ of the respective FIGS. 1A through 10A.

First, as shown in FIG. 1, a silicon germanium (SiGe) layer 2 as a first semiconductor layer is formed on a silicon substrate 1 which is a bulk silicon wafer, and a silicon (Si) layer 3 as a second semiconductor layer is formed thereon. The silicon germanium layer 2 and the silicon layer 3 are both grown epitaxially. The silicon layer that acts as a buffer may be formed before forming the silicon germanium layer 2.

Next, as shown in FIG. 2, a photoresist film 4 is patterned so as to open portions that become support holes 5 (as described hereafter) and to cover the remaining portion.

Then, as shown in FIG. 3, using the patterned photoresist film 4 as a mask, the silicon layer 3 and the silicon germanium layer 2 are successively etched to expose the surface of the silicon substrate 1 so that the support holes 5 are formed. After forming the support holes 5, the photoresist film 4 is removed.

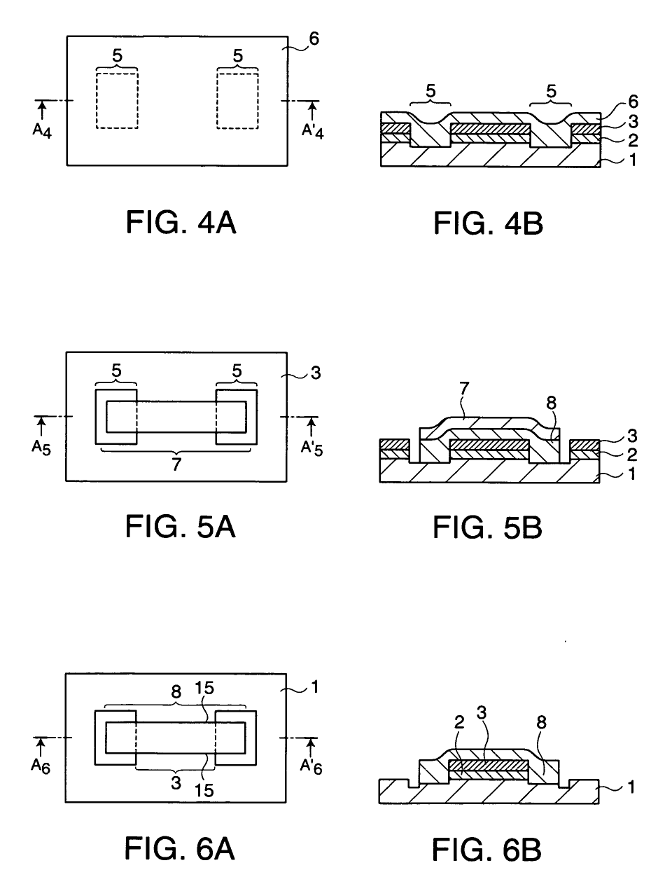

Thereafter, as shown in FIG. 4, a support formation layer 6 composed of silicon oxide or the like is formed by a method such as a chemical vapor deposition (CVD) method, filling the support holes 5 at the entire upper part of the silicon substrate 1 and covering the silicon layer 3.

Then, as shown in FIG. 5, by using a patterned photoresist film 7 as a mask, the support formation layer 6 is etched to form a support 8 out of the support formation layer 6. When forming the support 8, the photoresist film 7 is so patterned that an element region 11 (as described hereafter) having the SOI structure composed of the silicon (Si) layer 3 can be obtained in a manner that the element region 11 is supported by the support 8.

Thereafter, as shown in FIG. 6, by using the photoresist film 7 as a mask, the silicon layer 3 and the silicon germanium layer 2 are etched to expose the silicon substrate 1 and to expose, simultaneously, element region side surfaces 15. After etching the silicon layer 3 and the silicon germanium layer 2, the photoresist film 7 is removed.

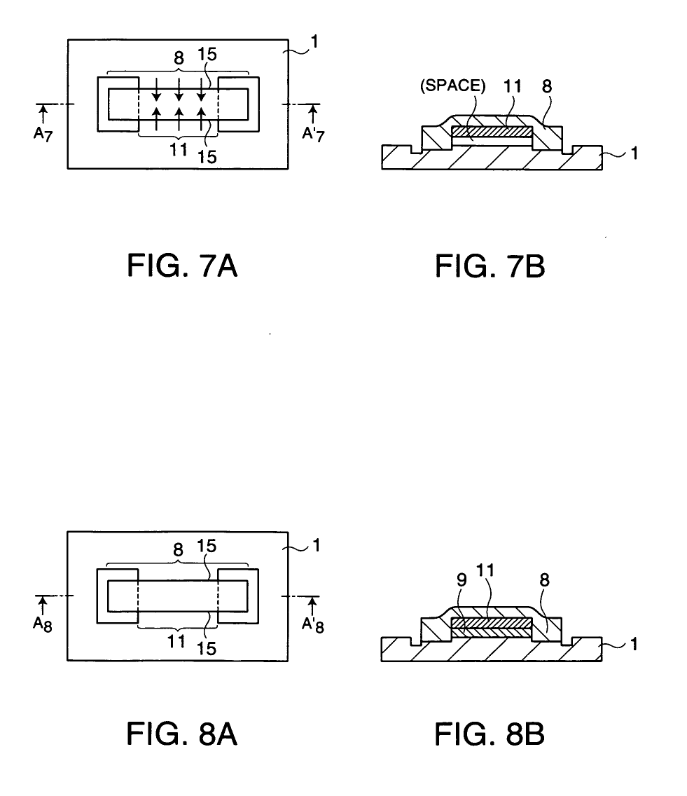

Next, as shown in FIG. 7, using an etch solution such as fluoronitric acid whose etch speed largely differs between the silicon layer 3 and the silicon germanium layer 2, the silicon germanium layer 2 is selectively etched from the side of the element region side surfaces 15 so that the element region, being supported by the support 8 and composed of the silicon layer 3, becomes mechanically afloat.

The width of the element region 11 will now be described. The size of the element region 11 is prescribed by the width of the photoresist film 7. The width of the photoresist film 7 is W1; the etch speed of the element region 11 is V1; the etch speed of the silicon germanium layer 2 is V2; the etch time is t; and the tolerable etch amount in the etch of the element region 11 is S. An etch amount T1 of the silicon germanium layer 2 for the time t is expressed as below.
T1=t×V2

Then, if the etch is to progress in the directions of the arrows in FIG. 7, the etch needs to be carried out until W1/2 for one side in order to remove the silicon germanium layer 2. Thus, it is necessary that the width W1 of the photoresist film 7 satisfy the relation below.
W1/2<t×V2

By performing the etch, the silicon layer 3 is also parasitically etched. Since the tolerable etch amount of the element region 11 is set at S, it is necessary to satisfy the relation below in order to keep the parasitic etch amount of the silicon layer 3 to be smaller than the tolerable etch amount S.
S>t×V1

Now, the etch speed ratio of V1 to V2 is defined as selectivity and expressed as R. A width W2 of the element region, which enables removal of the silicon germanium layer 2 in a state that the parasitic etch amount of the silicon layer 3 is kept at the tolerable etch amount S or less, needs to satisfy the relation below.
W2<2×S×R

By selecting the width W2 of the element region to satisfy the above relation, it becomes possible to remove the silicon germanium layer 2 and to control the contamination caused by the germanium residue.

Typically, if the tolerable etch amount S of the element region 11 is 5 nm and the selectivity is 200, the width W2 of the element region becomes 2 μm. When forming the SBSI in this condition, the germanium residue can be avoided by maintaining the width W2 of the element region to be narrower than 2 μm.

Next, as shown in FIG. 8, the silicon substrate 1 is subjected to thermal oxidation so as to form a buried insulating layer (BOX layer) 9 composed of silicon oxide between the element region 11 and the silicon substrate 1. The method for forming the buried insulating layer is not limited to the thermal oxidation of the silicon substrate 1, and the buried insulating layer 9 may be formed using a method such as a CVD method.

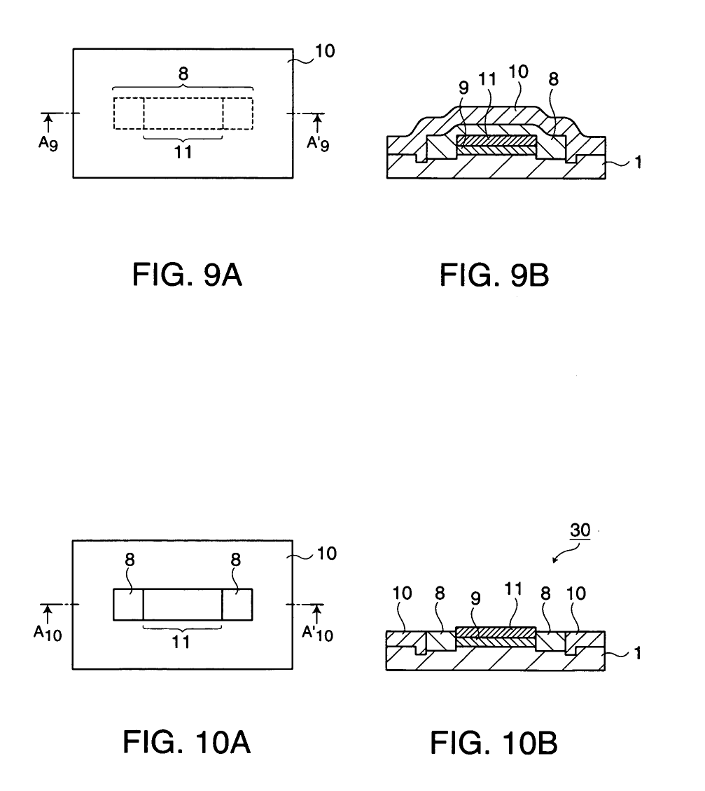

Then, as shown in FIG. 9, an insulating layer 10 made of silicon oxide or the like for element separation is formed on the entire surface above the silicon substrate 1 by a method such as CVD.

Next, as shown in FIG. 10, the entire surface above the silicon substrate 1 is planarized by a process such as chemical-mechanical polishing (CMP). Subsequently, when part of the insulating layer 10 is etched using buffer hydrofluoric acid or the like to expose the element region 11, and the structure (SOI structure) in which the elements are separated by layers such as the insulating layer 10 and the buried insulating layer 9 is formed into the silicon substrate 1, a semiconductor substrate 30 is completed.

As described hereinbefore, according to the method for manufacturing the semiconductor substrate 30, the SBSI structure can be fabricated in a state that germanium is not remained. If the germanium is incorporated in the element region 11 when forming the gate insulating film of the transistor on the element region 11, it is forced through the gate oxidation film and gathers at the interfaces between the element region 11, the gate insulating film, and silicon. This may generate the increase in the leakage current, Qbd deterioration, and decrease in the mobility of the gate insulating film. By using the above-described method for manufacturing the semiconductor substrate 30, however, it is possible to provide the method for manufacturing the element region 11 that is capable of controlling the occurrence of the problems caused by the germanium contamination.

Second Embodiment

Next, the semiconductor device of the second embodiment of another aspect of the invention will be described.

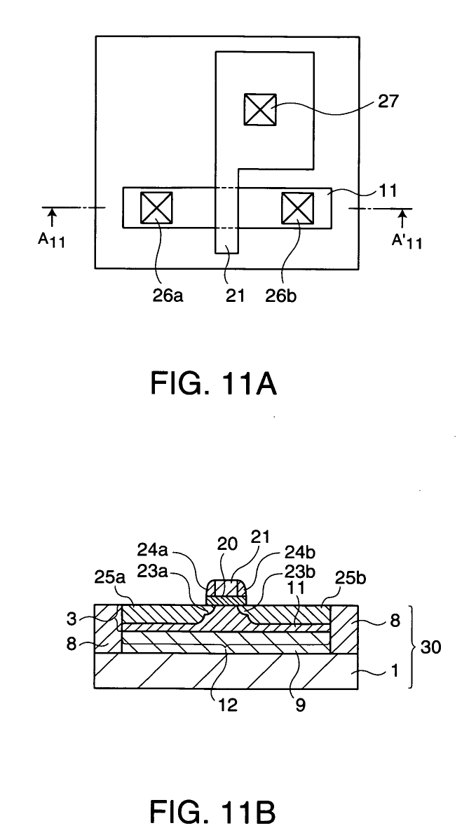

A transistor 12 as the semiconductor device is formed as shown in FIG. 11 using the SOI structure shown in FIG. 10. Hereafter, the manufacturing process will be briefly explained.

First, a gate insulating film 20 is formed on the surface of the element region 11 by treating the surface with thermal oxidation. Then, a polycrystalline silicon layer is formed over the element region 11 having the gate insulating film 20 formed thereon by a method such as CVD. Thereafter, the polycrystalline silicon layer is patterned by a photolithography technique so as to form a gate electrode 21 on the gate insulating film 20.

Then, using the gate electrode 21 as a mask and ion-implanting impurities such as As, P, or B in the element region 11, LDD layers 23a and 23b composed of low-concentration impurity introduction layers arranged on both sides of the gate electrode 21 are formed on the element region 11. Then, an insulating layer is formed by a method such as CVD on the element region 11 having the LDD layers 23a and 23b formed thereon, and by etching back the insulating layer by dry etch such as reactive ion etching (RIE), sidewalls 24a and 24b are formed on the walls of the sides of the gate electrode 21. Then, by using the gate electrode 21 and the sidewalls 24a and 24b as a mask and ion-implanting impurities such as As, P, or B in the element region 11, source/drain layers 25a and 25b composed of low-concentration impurity introduction layers arranged on the sides of the sidewalls 24a and 24b are formed on the element region 11. Then, when contacts 26a, 26b, and 27 are arranged, the transistor 12 as the semiconductor device is formed on the semiconductor substrate 30 in the SOI structure.

The transistor 12 as the semiconductor device formed on the semiconductor substrate 30 by these processes is capable of suppressing deterioration of its performance, since the incorporation of germanium into the element region 11 is prevented as described in the first embodiment. Therefore, it is possible to provide the high quality transistor 12 capable of suppressing the occurrence of phenomena such as abnormality in the gate current value, Qbd deterioration, and decrease in mobility.

The embodiments of the invention have been described using silicon as a material for the semiconductor base material. However, other material such as Ge, SiGe, SiC, SiSn, PbS, GaAs, InP, GaP, GaN, or ZnSe may be used.

Also, the embodiments of the invention have been described using silicon germanium as a material for the first semiconductor layer and silicon as a material for the second semiconductor layer. However, the layer combination may be such that the etch selectivity of the second semiconductor layer is lower than that of the first semiconductor layer. For example, for the first and second semiconductor layers, a combination of materials selected from Ge, SiC, SiSn, PbS, GaAs, InP, GaP, GaN, ZnSe, and the like may be used.

What is claimed is:

1. A semiconductor substrate manufacturing method, comprising:
forming, on an active surface side of a semiconductor base material, a first semiconductor layer whose etch selectivity is higher than that of the semiconductor base material;
forming over the first semiconductor layer a second semiconductor layer whose etch selectivity is lower than that of the first semiconductor layer;
forming a support hole so as to expose the semiconductor base material by partially removing and opening the second and first semiconductor layers around an element region;
forming a support formation layer on the active surface side of the semiconductor base material by filling the support hole and covering the second semiconductor layer;
forming, through etching, an opening surface that exposes part of end portions of a support and the first and second semiconductor layers located under this support, leaving a region including at least part of a region for the support hole and the element region;
forming a cavity between the second semiconductor layer of the element region and the semiconductor base material by selectively etching the first semiconductor layer via the opening surface;
forming a buried insulating film in the cavity;
forming a planarized insulating film on the active surface side of the semiconductor base material; and
removing, after planarizing the active surface side of the second semiconductor layer, the support formation layer remaining at a position where it covers the second semiconductor layer or at least part of a layer derived from the planarized insulating layer so as to expose the element region;
wherein, when the selective etch is performed while keeping a maximum width of the element region to be narrower than a width expressed as 2×S×R in which S is a tolerable etch amount of the second semiconductor layer that is etched simultaneously with the first semiconductor layer in the selective etch, and R is a selectivity between the first semiconductor layer and the second semiconductor layer in the selective etch, the first semiconductor layer is removed in a state that a parasitically etched amount of the second semiconductor layer is kept at the tolerable etch amount S or less.

2. The semiconductor substrate manufacturing method according to claim 1, wherein: the semiconductor base material is a bulk silicon substrate; the first semiconductor layer is a silicon germanium layer; and the second semiconductor layer is a silicon layer.

3. A semiconductor device having a transistor using, as a composition element, the element region obtained by conducting the semiconductor substrate manufacturing method of claim 2.
